(19) United States
(12) Patent Application Publication
(10) Pub. No.: US 2011/0299234 A1
(43) Pub. Date: Dec. 8, 2011

(54) PORTABLE DIGITAL GRAPHICAL DISPLAY SYSTEM WHICH CAN BE DISMANTLED

(75) Inventors: Andrés Leyva Arboleda, Bogota (CO); Hamilton Lopez Caro, Bogota (CO)

(73) Assignee: GLOBOTECH DISPLAYS DE COLOMBIA S.A., Bogota (CO)

(21) Appl. No.: 13/202,177

(22) PCT Filed: Jul. 16, 2010
(86) PCT No.: PCT/IB2010/001753

§ 371 Date: Aug. 18, 2011

(30) Foreign Application Priority Data
Jul. 23, 2009 (CO) 09076711

(51) Int. Cl. H05K 7/00

(52) U.S. Cl. 361/679.01

(57) ABSTRACT

The present invention lies in the field of devices or systems for disclosing information. Specifically, the present invention relates to a digital system for graphically displaying information with various applications such as, inter alia, advertising, commercial information, signposts, instructions, said system being able to be dismantled and being lightweight and portable: in addition, said system can be packed in a special hard container which may include wheels on the base thereof in order to facilitate the transport thereof to any location. The system in the present invention is thus simple and versatile with respect to conventional display devices of this type since the system is simple to assemble/disassemble, is convenient for handling all types of information, is very attractive to consumers and allows the information to be taken to sites of interest, which significantly improves the impact on the target audience. Conventional screen systems are completely fixed structures with additional restrictions and requirements for the installation thereof which greatly limit the handling and versatility of the information at particular sites. The present system surpasses all of the advantages of these conventional systems by virtue of the specific arrangement of the elements thereof which can be assembled and dismantled without great difficulty and thus having the digital graphical information at any time and in any place wanted or required.

### FIELD OF THE INVENTION

The present invention relates to devices or systems for disclosing information. Specifically, the present invention relates to a graphical digital information display system, which is simple, light, demountable, and portable, given that it can be packed and transported in a special hard container which includes a base having wheels. Thus, the device of the present invention turns to be attractive and economical with respect to those conventional systems of the same type, which is absolutely desirable to the user or targeted public.

### BACKGROUND

It is well known in the state of the art that publicity constitutes a very useful tool for disclosing information to public. In order to achieve this purpose, publicity has various information disclosure techniques, among which we find graphical display systems. Currently, the “graphical display” systems are used along with rigid printed images having an ephemeral character which the user has to change each time he/her wishes to transmit a new message, which turn to be costly at long-term and not very efficient. Besides, the advertised message has a low effect with the receptor and losses impact, given that the action field is restricted to visual. Thus, the amount of information transmitted to the receptor is significantly reduced, and it is necessary to lean on the support of other means in order to better explain the message. Furthermore, the greater part of the conventional information disclosing systems are fixed structures which do not allow an easy removal from the location in which they are placed or the possibility of multiple changes with a very low cost.

Therefore, starting with such limiting drawback of the conventional information disclosing systems, generally one has to lay on the broadcasting of the message through media allowing greater dynamism and impact, such as screens and image projectors. Nevertheless, these systems must have sound and reproduction devices which increase the space occupied by the system and blocks any possible displacement. In fact, some of those systems requires permanent, complex, heavy and large size structures on which can be supported.

Furthermore, when assembling these systems one must count on the support of trained personnel as the technical difficulties with equipment and structures must be solved; also, when it is required to broadcast a message from a different location, these systems cannot be easily disassembled and reassembled, which makes the communication process more slow. In addition, the message is limited by the capacity of the reproduction equipment, and its renewal is manual therefore the coordination and advertising campaigns decrease.

Therefore, it is clear that there still is in the state of the art of advertising or information disclosure, the urgent need of a novel graphic information disclosure system which is digital, demountable, light weight, portable, which can be easily transported when packed in a special container having wheels on its base, easy to install and operate, which, in addition, turns to be attractive to the receptor, and which significantly improves the previously discussed technical drawbacks concerning the exhibition of conventional graphical information.

### DESCRIPTION OF THE FIGURES

The digital graphical display system of the present invention can be better understood by making reference to the annexed Figures:

FIGS. 1 to 10 describe each of the components forming a preferred form of the system of the present invention.

FIGS. 11 to 24 represent the way the components are assembled to form the digital graphical display system of the present invention.

FIGS. 25 to 28 show the plan and perspective views of the digital graphical display system of the present invention.

FIG. 29 shows a perspective view which exhibits in a fragmented manner each one of the components forming the digital graphical display system of the present invention.

FIGS. 30 to 32 show various perspective views of the digital graphical display system of the present invention as several preferred forms.

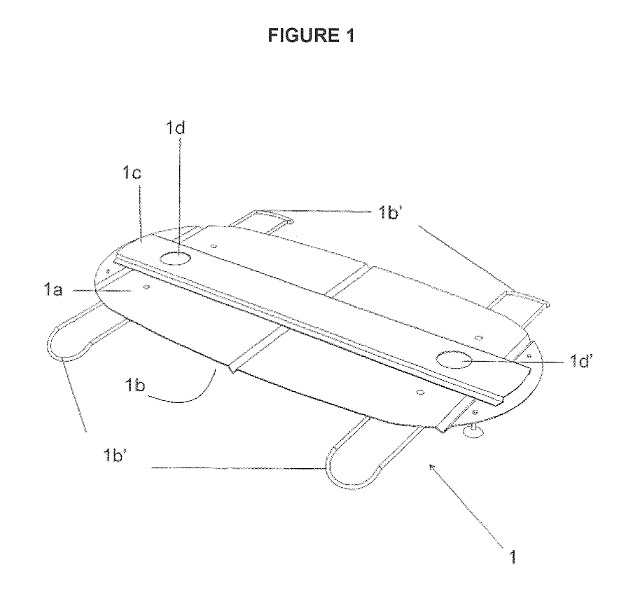

FIG. 1 is a perspective view of the base.

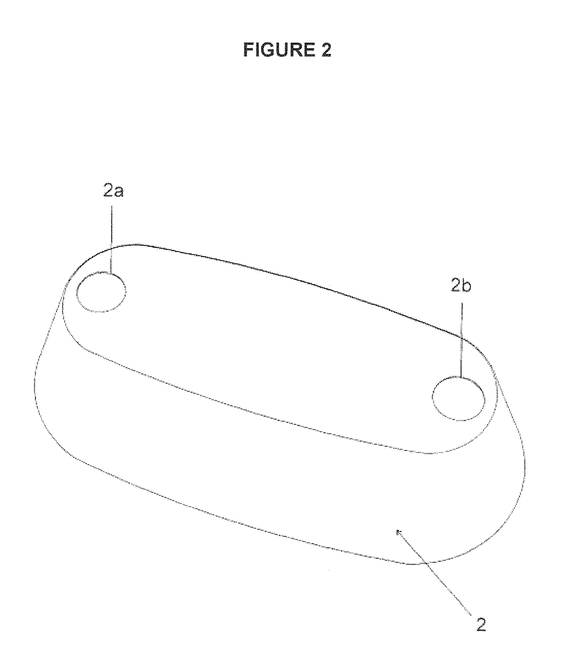

FIG. 2 is a perspective view of the housing covering the base.

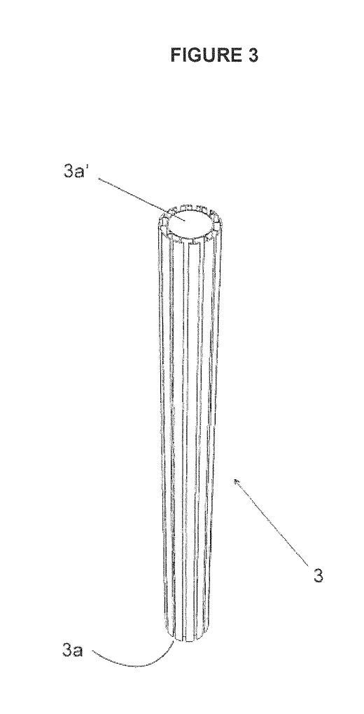

FIG. 3 is a perspective view of the support columns of the system.

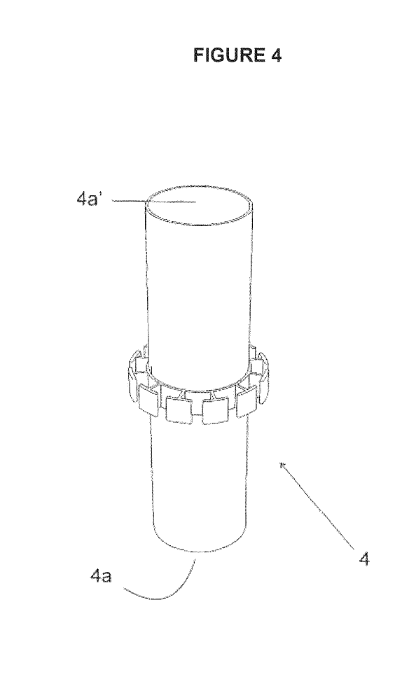

FIG. 4 is a perspective view of the connection tube linking the support columns of the system.

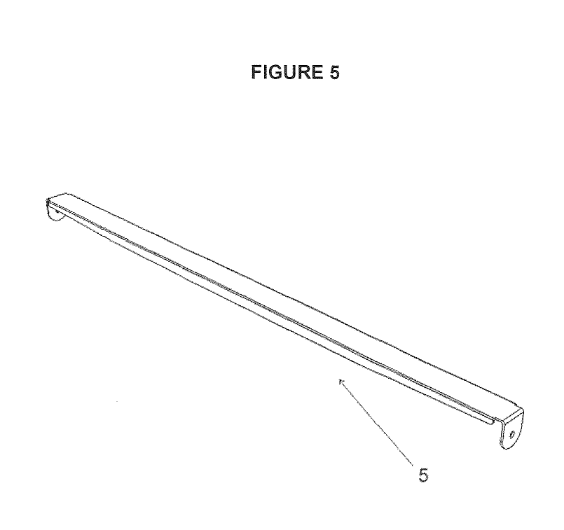

FIG. 5 is a perspective view of the link structure of the columns and support of the structural housings of the system.

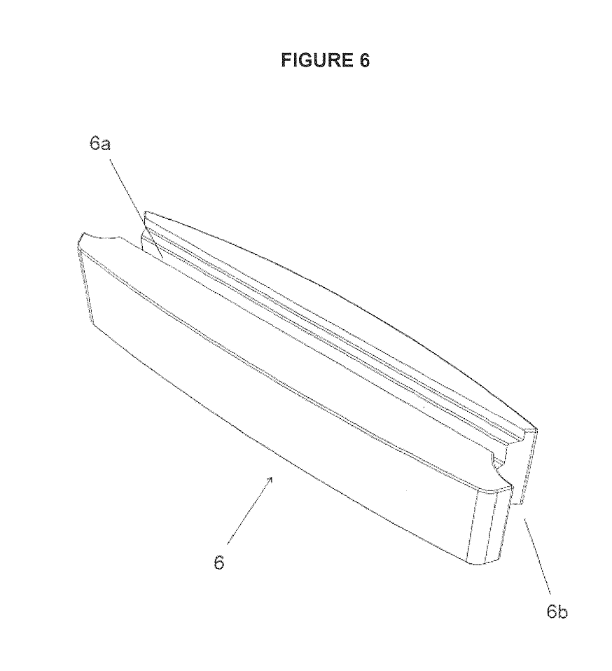

FIG. 6 is a perspective view of the structural housings of the system.

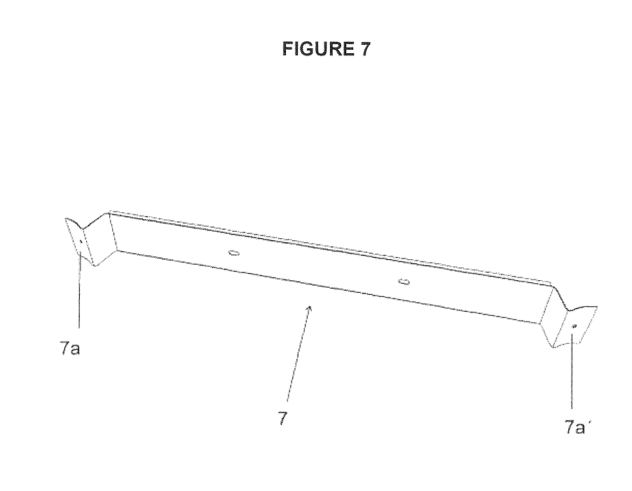

FIG. 7 is a perspective view of the vertical component which protects the front part of the screen of the system.

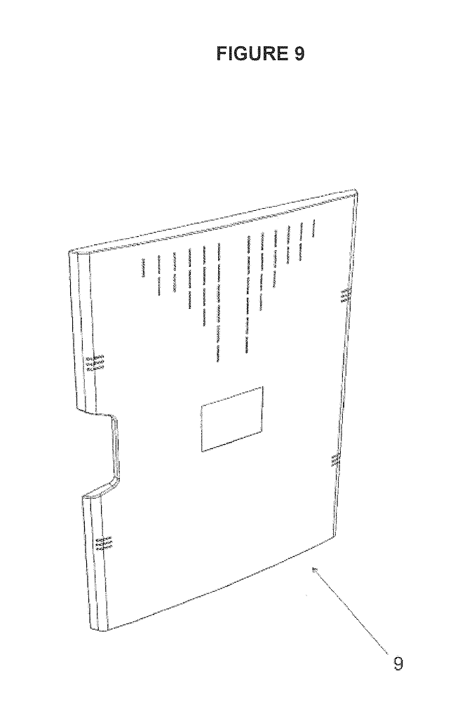

FIG. 9 is a perspective view of the component protecting the screen on the rear part and which allows the refrigerating air circulation.

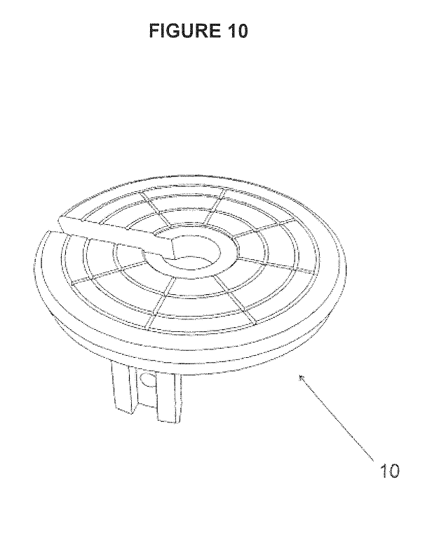

FIG. 10 is a perspective view of the covers of the support columns of the system.

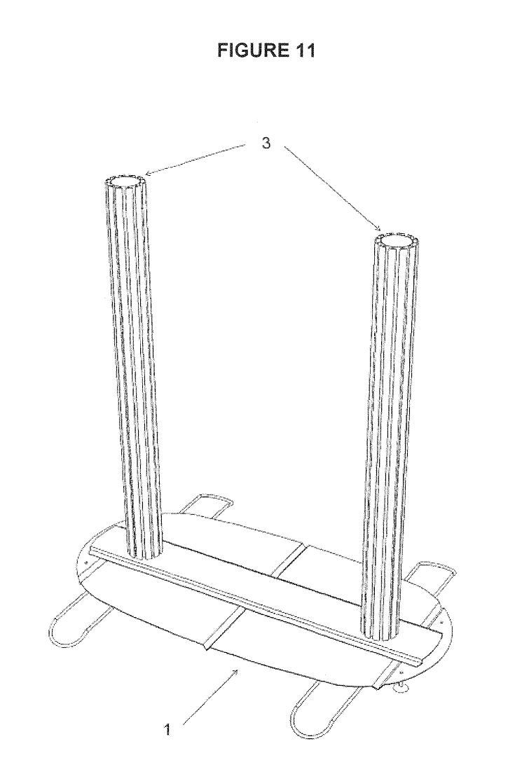

FIG. 11 is a perspective view of the digital graphical display system showing the components forming the support of the system.

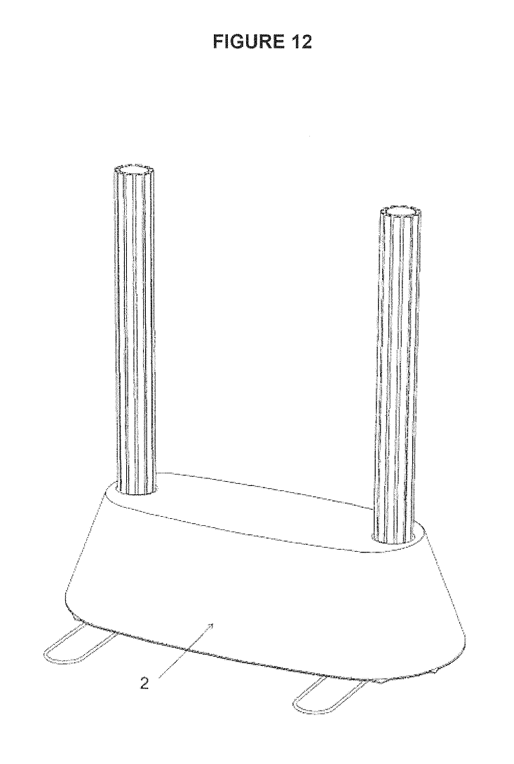

FIG. 12 is a perspective view of the digital graphical display system which shows the coating of the base with an elongated surface covering same.

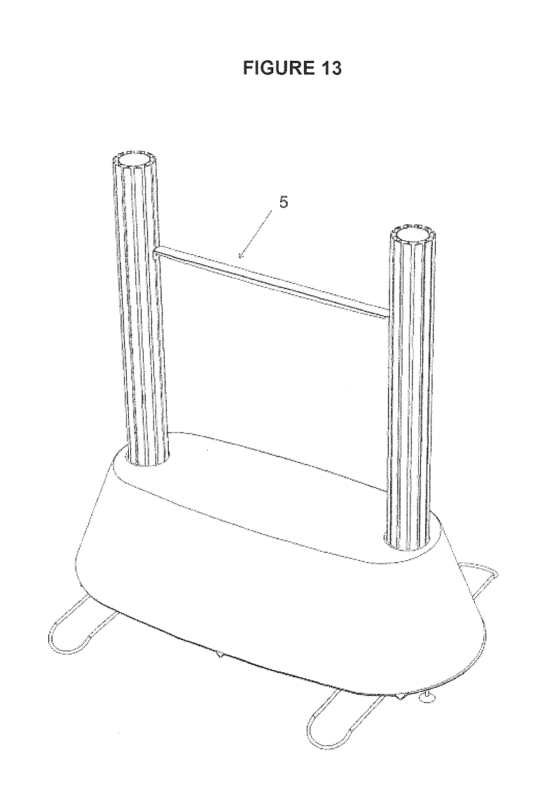

FIG. 13 is a perspective view of the digital graphical display system which shows a metal structure screwed to the grooves of the lower columns.

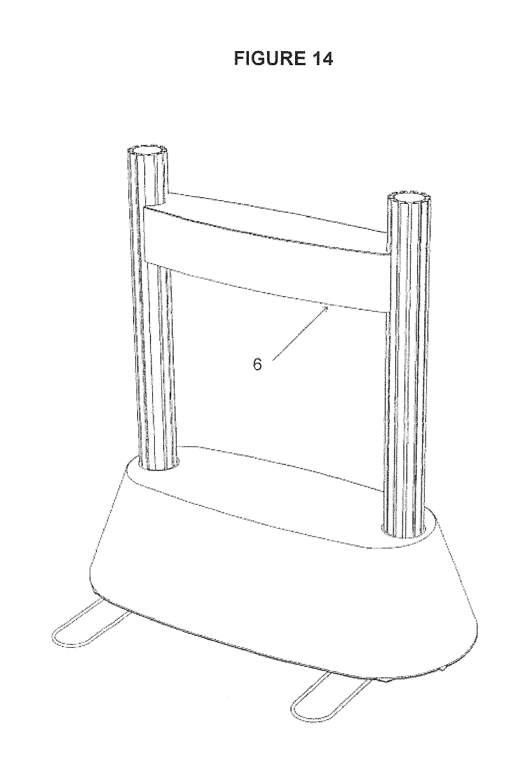

FIG. 14 is a perspective view of the digital graphical display system which shows a first structural cover housing.

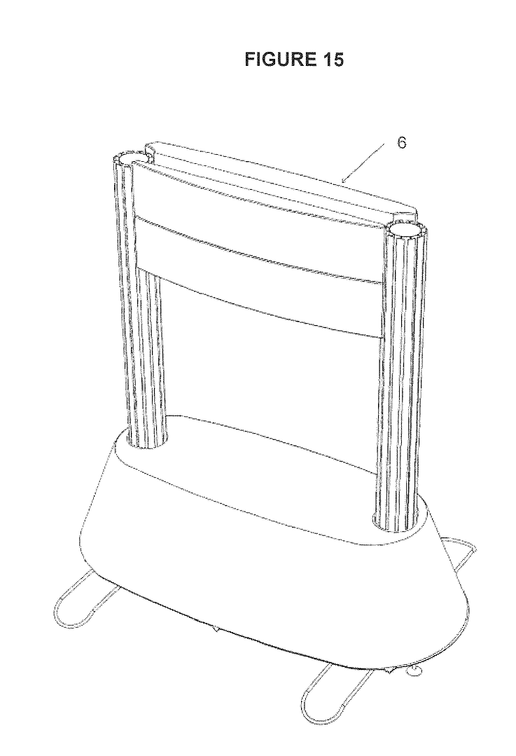

FIG. 15 is a perspective view of the digital graphical display system which shows a second structural cover housing supported on the first.

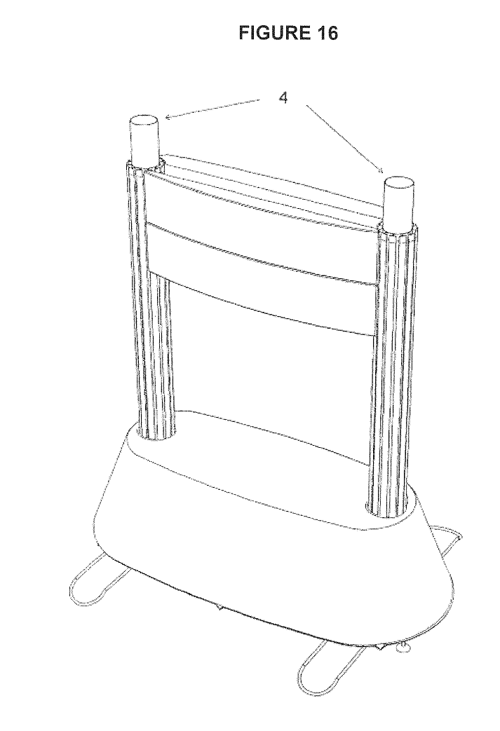

FIG. 16 is a perspective view of the digital graphical display system showing the assembly of the tubes connecting to the lower columns.

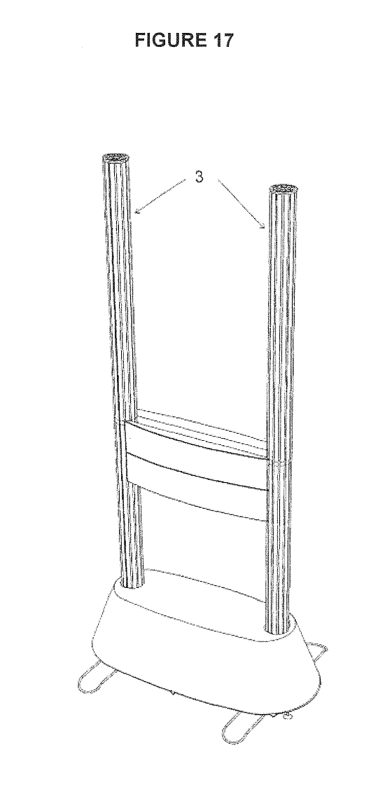

FIG. 17 is a perspective view of the digital graphical display system showing the assembly of the top columns into the system through the connecting tubes.

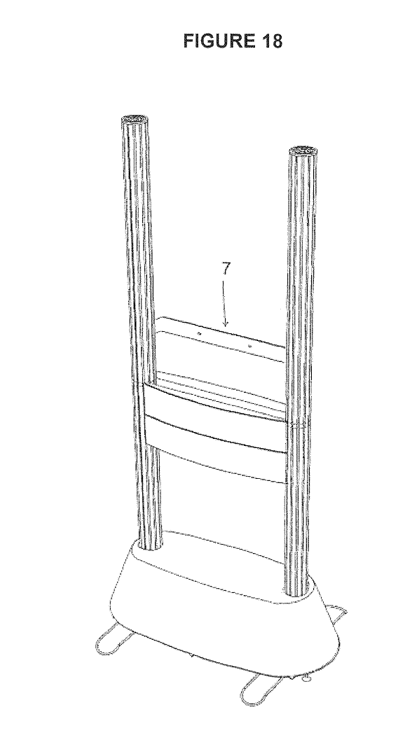

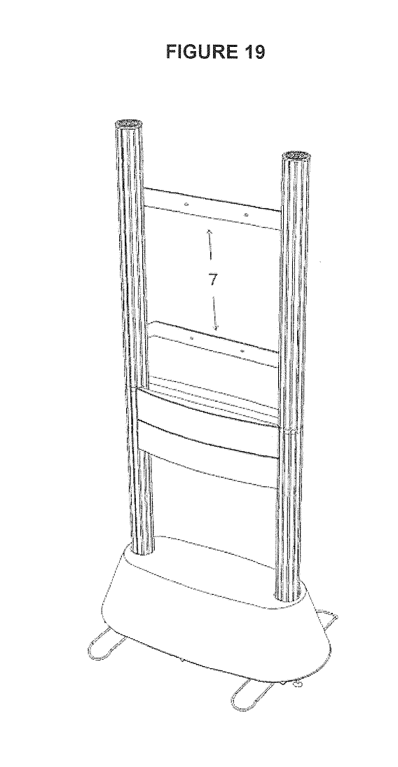

FIGS. 18 and 19 are perspective views of the digital graphical display system which show the assembly of the metallic pieces to the top columns which serve as coupling of the system screen.

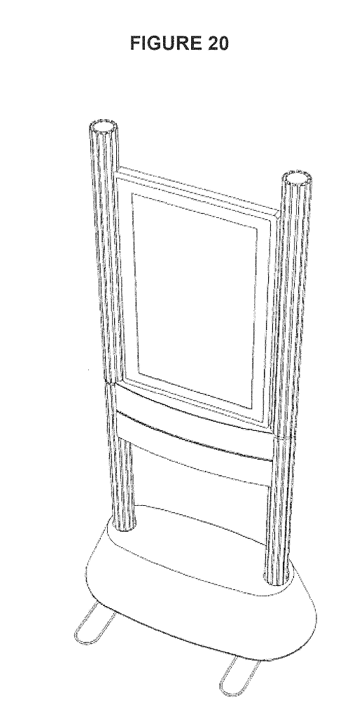

FIG. 20 is a perspective view of the digital graphical display system which shows the adjustment of the screen between the columns and the second structural cover housing.

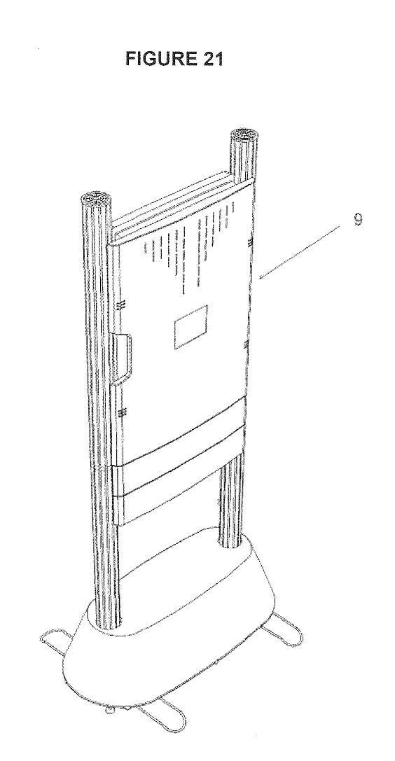

FIG. 21 is a perspective view seen from behind the digital graphical display system which shows the adjustment of the protecting sheet between the columns.

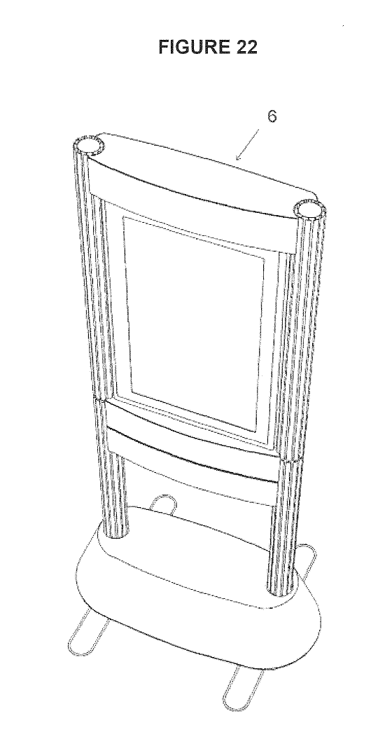

FIG. 22 is a perspective view of the digital graphical display system which shows a third housing having an elongated surface.

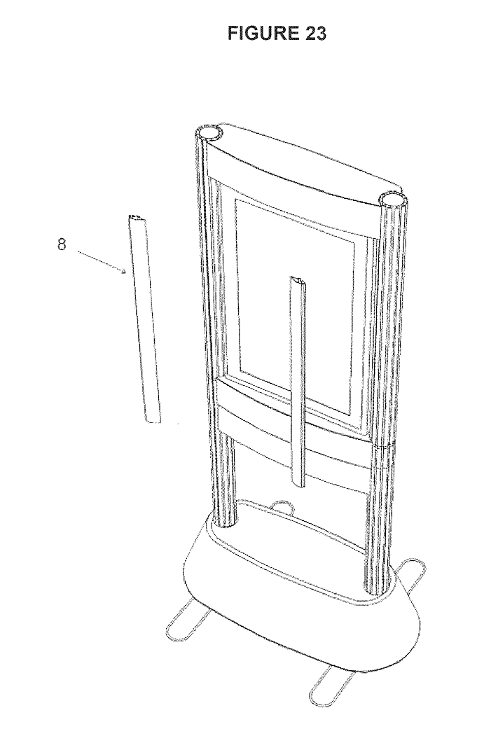

FIG. 23 is a perspective view of the digital graphical display system which shows the elongates pieces having rounded edges which fit on the screen for its protection.

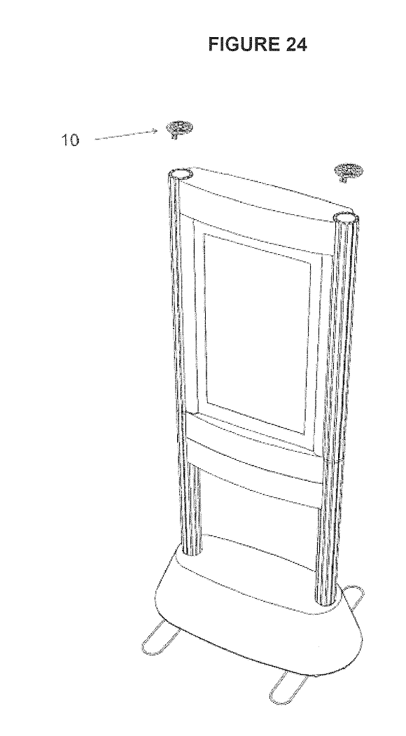

FIG. 24 is a perspective view of the digital graphical display system showing the circular covers coupled to the end of the top elongated tubes.

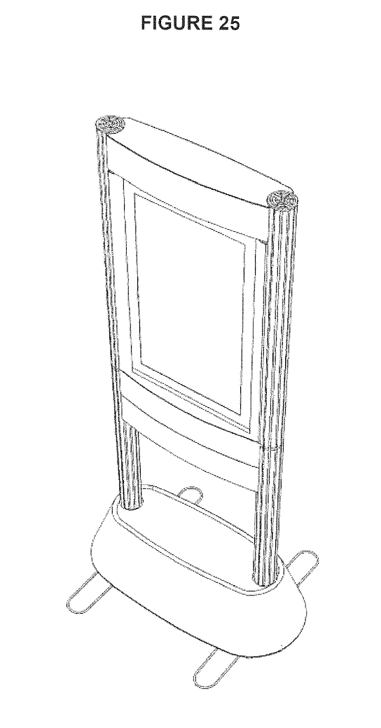

FIG. 25 is a perspective view of the digital graphical display system.

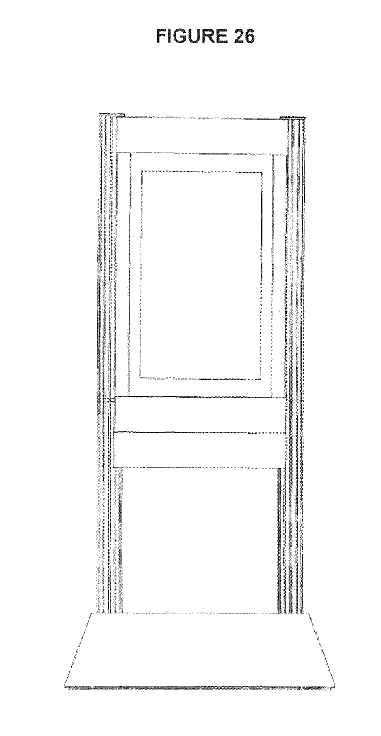

FIG. 26 is a frontal view of the digital graphical display system of FIG. 25.

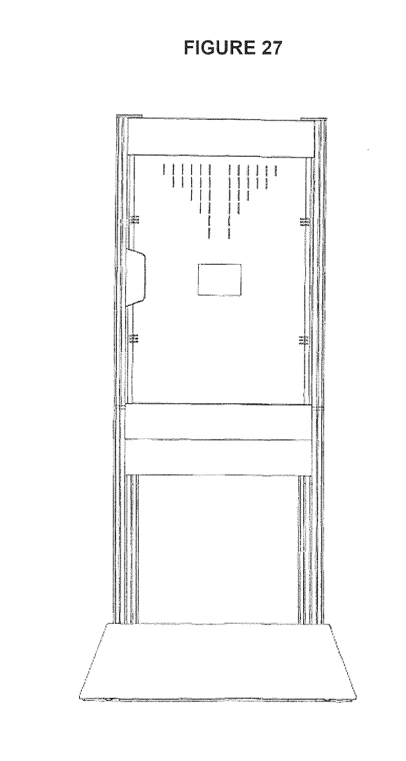

FIG. 27 is a rear view of the digital graphical display system of FIG. 25.

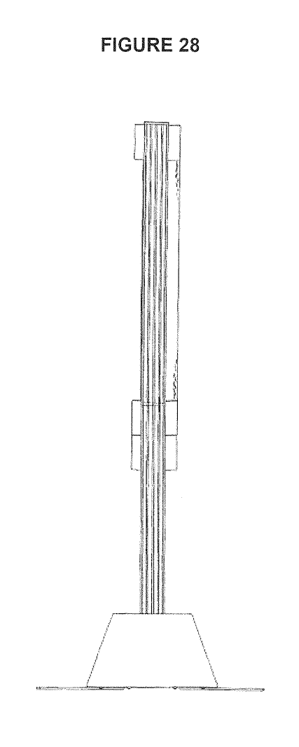

FIG. 28 is a right side view of the digital graphical display system of FIG. 25, the left side view is a mirror image of the previous one.

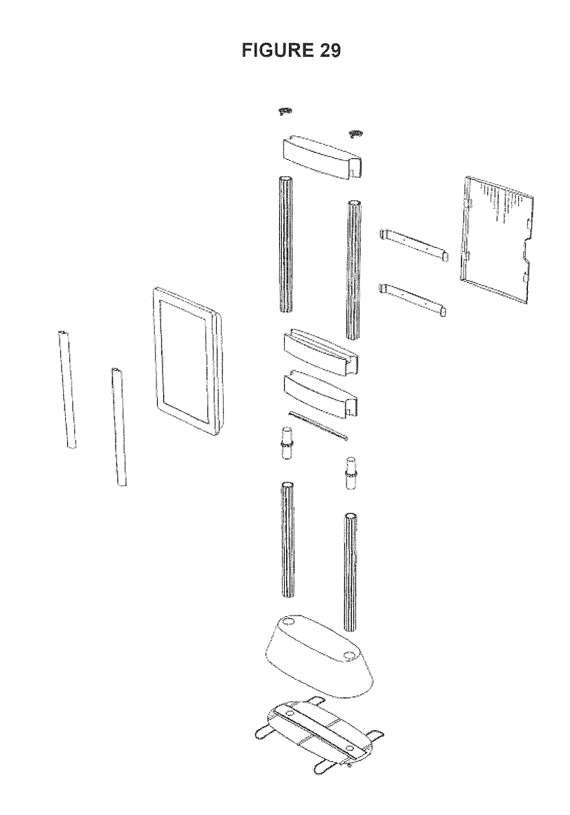

FIG. 29 is a perspective view of FIG. 25, which shows an explosion view of the components forming the system of the invention.

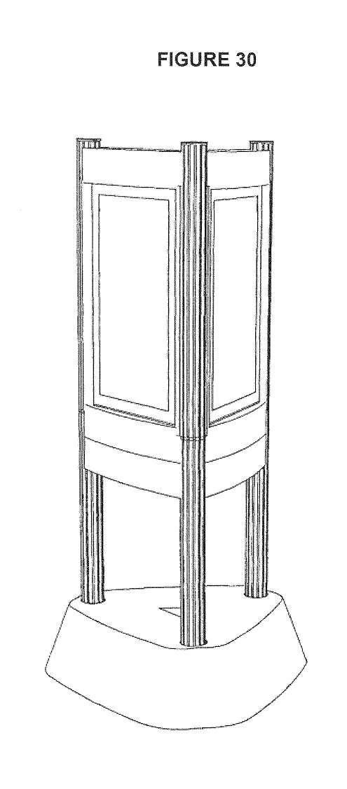

FIG. 30 is a perspective view of a preferred embodiment of the system of the present invention in which three screens are provided on a trapezoidal base.

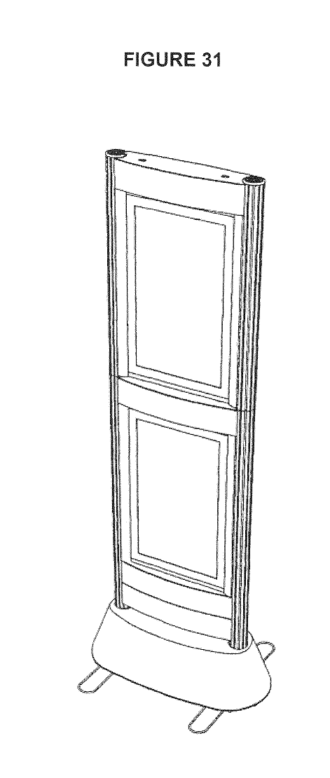

FIG. 31 is a perspective view of a preferred embodiment of the system of the present invention in which two screens are provided on one single base.

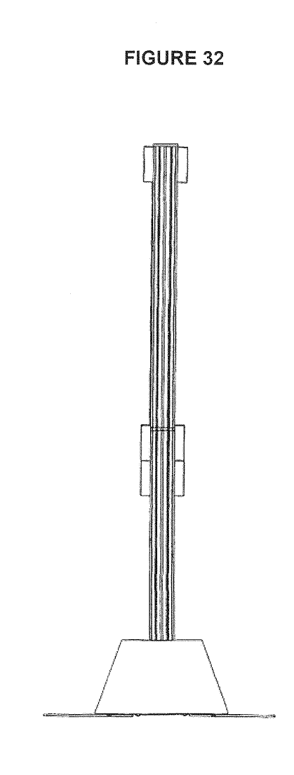

FIG. 32 is a perspective view of a preferred embodiment of the system of the present invention in which a two-face screen is provided on one single base.

### DETAILED DESCRIPTION OF THE INVENTION

In order to overcome the limitations and drawbacks of mentioned conventional stationary systems for displaying information and publicity, the inventors of the present invention had designed a novel digital graphical display system which allows easy assemble and disassemble and to be portable, light, simple and efficient in managing the information which want to be displayed; and in addition, results to be highly attractive to the receptor of the information, because its components are designed and specifically provided for achieving advantages. In that manner, the present invention discloses a novel system for digitally displaying graphic information having multiple applications, among which there are, commercial information, signaling in several locations requiring it, descriptions in museums, information for hospitals, airports, universities, conferences, theatres, official entities, etc.

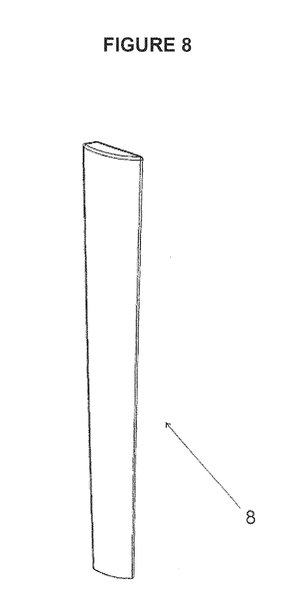

Thus, the present invention provides in a first embodiment, a digital graphical display system which is demountable and portable, characterized in that it comprises a base (1) of FIG. 1 consisting of an elongated sheet exhibiting an inner surface (1a) and an outer surface (1b), and four support rods (1b′) transversally located under the sheet on its outer surface (1b); while along the sheet, longitudinally and on its inner surface (1a) there is provided an elongated piece (1c) along the entire sheet, and on which there are at least two support apertures (1d, 1d′) in its ends; an elongated surface or housing (2) of FIG. 2 acting as a cover which exhibits an open wider end assembled to the base (FIG. 1) in a perpendicular manner and a narrower closed end in which two reinforced apertures (2a, 2b) are located in its ends through which two lower elongated support elements or columns (3) of FIG. 3, pass, which are in turn inserted through one of its ends (3a) into each one of the support apertures (2d, 2d′), the other ends (3a′) of said elongated support elements coupled to two connecting pieces (4) of FIG. 4 through its ends (4a) while through the ends (4a′) of said connecting pieces two other upper elongated support elements or columns (FIG. 3) are connected; said connecting pieces (FIG. 4) have on its mid part a segment having grooves, and in such way are transversally held between said upper elongated elements (FIG. 3) a metal piece (5) of FIG. 5 as a crossbar; the metal piece (FIG. 5) is covered by an elongated structure or housing (6) of FIG. 6, which has in one of its faces a stepping transverse recess (6a) as support on the metal piece (FIG. 5), and when the piece is inverted using these recesses to lean on a screen, and on the short sides of this elongated surface or housing (6b) there is an inwards semi-aperture configuration for coupling in a complementary manner to the elongated elements (FIG. 3); at least an elongated support piece (7) of FIG. 7 is transversally coupled to the upper elongated elements (FIG. 3) for adjusting a screen, through its concave-shaped ends, and having distant holes (7a, 7a′) which allow them to be secured to the elongated elements (FIG. 3); the front part of the system includes two elongated pieces (8) of FIG. 8 having rounded edges on its front surface thus protecting the screen and an inner surface having fasteners along them for coupling to the system, while the rear part of the system on its upper portion includes a concave rectangular structure (9) of FIG. 9 having apertures distributed on each corner; and which are in turn covered by an elongated structure (FIG. 6), which in one of its faces has a stepping transverse recess (6a) to lean on the metal piece (FIG. 5), and when the piece is inverted such recesses serve as support to the screen, and which short sides of said elongated surface or housing (6b) exhibit an inwardly semi-aperture configuration for coupling in a complementary manner to the elongated elements (FIG. 3); a circular lid (10) of FIG. 10 is coupled to the ends of the upper elongated elements (3a), said lid has a central hole and a groove which extends up to the final edge of the circle, and which further has a vertical piece for inserting into the channels of the upper elongated elements (FIG. 3) and a threaded hole for securing through a screw.

In the preferred embodiments of the invention, the base (FIG. 1) of the display system can be configured with any kind of geometric shape, among which it includes, without limitation, square, rectangular, circular, oval, elliptic, triangular, trapezoidal, polyhedral, among others. In fact, that person skilled in the art will understand that any geometric configuration is possible always and when it complies with the practical purpose of the digital graphical display system of being demountable and portable.

The elongated sheet forming the base (FIG. 1) can include at least one groove transversally provided on said sheet, in other preferred embodiments.

Other embodiments yet more preferable comprise the base (FIG. 1) which can include on its outer face (1b) several floor attaching systems, among which it includes, fixed or demountable bases, wheels, sucks, height levelers, among others, which help the displacement and adjustment of the display system of the present invention, once assembled. In that same outer face, the supports rods are attached through bolts and rivets which allow said pieces to inwardly pivot, which turn to be attractive to the consumer and facilitates reinforcing the base to the system.

Other preferred embodiments comprise the base (FIG. 1) which can include more than two support elements (1d, 1d′) located on another piece (1c′), such that two additional elongated elements can be included for supporting, for example, another screen counter-faced to the first screen. This kind of configuration with two screens can result more attractive to the consumer. In that order of ideas, a person skilled in the art will understand that the elongated surface or housing (FIG. 2) covering the base (FIG. 1) should include as much orifices (2a, 2b) as support elements (1d, 1d′) included in the base (FIG. 1). For example, if a trapezoidal base is required, the person skilled in the art will understand that three supporting elements and three elongated pieces (1c) will be included.

Also, it will be understood that the diameter of said orifices and that of the elongated elements which pass through said orifices will vary as the area of the closed side of said elongated surface (FIG. 2) allows it, and the purpose is totally practical in order to always achieve the ends of demountability and portability of the system.

It must be taken into account that an excessive weight due to excess of components can be disadvantageous and uncomfortable to the user as the versatility and portability of the system will be completely lost. Therefore, the system of the present invention achieves its practical ends of simplicity, assembly/disassembly, portability and economy when maintaining the essential structural components and an efficient relationship between size and weight. In fact, once disassembled, the digital graphical display system of the present invention, its components are stored in a special container for transportation. Said container is constituted by a hollow body or housing having an elongated and rectangular shape and a lid, which structure is rigid as to allow in an organized and secure way to store the system of the present invention, and thus avoiding deformities or damages to the components. Therefore, the container can be manufactured of any polymeric element that confers stiffness to the structure. The lid or cover includes an anchor system such as flanges designed to be demountably inserted in the grooves located in the container's body. In the same way, the lid includes a handle system, which may vary in design and configuration for grabbing the container in the part of the user. On the other hand, the base of the body includes a set of wheels which make easy the transport of the structure to any place.

Preferred embodiments wherein the elongated surface acting as cover (FIG. 2) which perpendicularly connects to the base (FIG. 1) can also acquire various geometric configurations depending on the geometric shape of the base (FIG. 1). In the same way, this elongated surface used as a cover (FIG. 2) can exhibit a variety of styles or trimmings on its outer surface which makes the display system more attractive to the users.

Other preferred embodiments of the invention have the top and lower elongated elements (FIG. 3) with geometric configurations such as circular, square, triangular, rectangular, polyhedral, or any other geometric form which results attractive to the user. A more preferred embodiment provides circular top and lower elongated elements (FIG. 3). In fact, these top and lower elongated elements (FIG. 3) can also vary its inner diameters, length and number of grooves depending on the needs of the consumer, the requirements of the market, or the manufacturing costs. What is important is that said elements have always at least two grooves for inserting the piece (FIG. 5) in them in order to support the screen. Another important aspect is that all the wiring of the screen or the accessories coupled to the display system of the present invention passes through inside of these elongated elements, such that remain invisible to the user.

Other preferred embodiments have an elongated surface (FIG. 6) which can also show different shapes and variations on its geometry, always and when said surface corresponds to a completely closed piece, which has on one of its faces a stepping transverse recess in order to lean on the piece (FIG. 5), and when the piece is inverted with these recesses lean on the screen; furthermore, forms a part of the attractive visual of the display system of the present invention. Yet more preferred embodiments show that another similar piece (FIG. 6) can be located on the elongated structure (FIG. 6).

Other preferred embodiments of the invention show two elongated rectangular support pieces (7) of FIG. 7 transversally coupled to the top elongated elements (FIG. 39 in order to fit a screen through its concave-shaped ends. The elongated rectangular pieces (FIG. 7) coupled to the system, will depend on the system style and the number of screens which need to be fit.

The concave rectangular structure (FIG. 9) protecting the rear part of the system in its top portion can exhibit various types of apertures on each corner, among which are included, orifices, grills, or any other geometric form allowing ventilation of the screen. The person skilled in the art will understand that said structure will not be present when the designed system requires two monitors face to face.

Other preferred embodiments have a 32″ size screen but it is understood that said dimension can vary depending on the technical specifications of the assembled system, and on the user's needs.

Even though the first embodiment generally describes the essential components forming the digital graphical display system of the present invention, the person skilled in the art will perfectly understand that the preferred embodiments constitute some exemplified limitations of certain specific shapes and configurations applicable to the system of the present invention.

### Components of the System

In order to build a digital graphical data display system, demountable and portable of the present invention, ten (10) essential pieces are required, which are described below, and a screen.

### Screen

Within the context of the present invention, screen must be understood as an image display electronic unit capable of directly reading memory units containing video and sound and can have a size of, for example, 32″ or 40″. A preferred embodiment of the invention is capable of reading external memory units or cards, thus avoiding the use of extravagant equipment such as computers or DVD players. Thus, the required “intelligent” monitor in the system of the present invention greatly differs from today stationary monitors, which use a TV, which in turn need a computer or a DVD player in order to be able to project an image, thus increasing costs, weight and discomfort of the system of the present invention. In that manner, the person skilled in the art will understand that in order to comply with the purposes of the present invention, the required screen to be fitted in the system does not correspond to any TV monitor requiring a DVD reproducing apparatus or a PC for disclosing information. It will be further understood that the size or number of intelligent screens used in the system of the present invention can vary depending on the requirements and needs of the market. For example, 16″, 21″, 24″, 32″, 40″, 42″, 46″, 50″ and 55″ screens.

Component 1: Corresponds to the base (FIG. 1) and consists of a sheet which can be made out of any resistant polymer, metal, glass fiber or wood agglomerates, re-structured with three strips of the same material located against its normal structure. It has four rotating legs in the lower part which provide support and stability to the system when needed.

Component 2: Correspond to a housing (FIG. 2), which is used to cover the component (FIG. 1). Its function is protecting and aesthetics.

Component 3: Corresponds to a hollow elongated element (FIG. 3) which is a column wherein all other pieces of the system are assembled and through grooves so that they can be adequately assembled. The wires required by the system pass through the holes of these columns.

Component 4: Corresponds to the connecting pieces (FIG. 4) for component 3. These are the coupling units for the two columns which are assembled in a continuous manner in the axial direction. These units are hollow in order to allow the wiring of the system to pass through.

Component 5: Corresponds to a union and support structure (5) of FIG. 5 which is assembled to the columns and has the role of aligning and adjusting the structure and providing support to the housing of the structural lid. The same is located underneath the bottom piece (FIG. 6) and allows its coupling to the system.

Component 6: Corresponds to a housing, which has on one of its faces a stepping transverse recess laid on component 5, and when the piece is inverted this recess provides support to the screen; on its ends the same has the adequate shape for exactly coupling with the columns (FIG. 3). Three units are required in a preferred embodiment of the system.

Component 7: Corresponds to the supports (7) of the screen (FIG. 7). Its ends have the adequate shape for exactly coupling with the columns (FIG. 3). Two units are required in a preferred embodiment of the system.

Component 8: Corresponds to the piece (9) which serves as a protector of the screen (FIG. 9) and which allows air circulation in order to cool down the screen. In addition, the same complies with an aesthetic function.

Component 9: Corresponds to the lids (10) of FIG. 10 which close the ends of the columns of FIG. 3 which remain exposed. These lid has a vertical piece which can be introduced into the grooves of component 3, and a threaded hole to secure it by a screw. It can be manufactured from a polymer, glass fiber, wood or agglomerates. Two units are required in a preferred embodiment of the system.

Component 10: Correspond to protecting vertical pieces (8) of FIG. 8 which protect the front part of the monitor and integrates the same to the system through fixation elements. It also has an aesthetic function.

The above components can be included in an organized and secure manner within a special container, such as that one previously described, in such manner that it is possible for the user to transport said disassembled components without major complications.

### Assembly of the System of the Present Invention

The following example constitutes an illustration on how to assemble a simple display system of a preferred embodiment of the present invention.

In first place, component 1 is located in position, corresponding to the base (1) of FIG. 1. Two components 3, corresponding to the columns, are connected by both ends on this base (FIG. 1), as shown in FIG. 11. If desired, the base can include additional grabbing systems onto the floor, such as legs, wheels, sucks, height levelers, among others.

Then, component 2, which corresponds to the housing (FIG. 2), is inserted and slipped until connecting component 1, base, as shown in FIG. 12. Further on, component 5, metal piece (FIG. 5), is located between components 3, columns, until its ends coincide with the lateral marks, then they are screwed at this point at each side in order to fix the piece, as shown in FIG. 13. Once this component 5 has been placed, component 6, the housing, is also slipped between the columns, until fitted in place, see FIG. 14. Again another component 6 is located directly on the first one until fitted. Components 4, corresponding to the connecting tubes (FIG. 4), are then introduced into each free end of the columns (3), see FIG. 16. On said connecting tubes (4) other columns (3) are connected, see FIG. 17. Later, a component 7, corresponding to the support piece of the screen, is screwed placing it on the bottom mark indicated on the latter located columns (3), see FIG. 18. Then, another component 7 is positioned on the top mark and is fastened, FIG. 19. A 32″ screen, for example, is screwed on these pieces until completely fixed, FIG. 20.

Once the screen has been located, component 8, corresponding to the piece used as screen protector and which allows air circulation, is taken and fitted in the rear part of the device screwing it onto components 7, FIG. 21. Then, leaning on the screen and between the top columns, the last component 6 is fitted on the screen thus forming one single set, FIG. 22. In front of the screen, components 10, which correspond to the vertical tubes (8), are brought closer, FIG. 23. Finally, components 10 are introduced, corresponding to the circular lids (10), in the free end of top columns (3), from the top part of the device and are screwed therein, FIG. 24.

FIGS. 25, 26, 27 and 28 show plan and perspective views of the display system of the present invention, once all components have been completely assembled in a predetermine location for disclosing digital graphical information.

FIG. 29 is a perspective view showing in a fragmentary manner each one of the components forming the display system of the present invention.

FIGS. 30, 31 and 32 show various perspective views of the display system of the present invention provided in various preferred forms, which result attractive to the consumer. For example, more than one screen can be combined arranged horizontally or vertically. It is also possible to use a double face screen, that is, one which allows visualization on both sides. In the same way, various display systems can be coupled such as those of the present invention in order to form much bigger and attractive structures for the user.

In addition, the system of the present invention can be integrally coupled to other display systems such as those of the present invention in order to form much bigger and attractive structures for the user.

Furthermore, the system of the present invention can be integrally coupled to other fixed display systems, due to its characteristic of being portable, in order to compliment in a versatile manner said fix systems.

The operation of the system of the present invention begins with its assembly, given that it is a device which is capable of being assembled by one individual in low amount of time, and using no specialized tools. In the same way, it is capable of being disassembled and easily transported to another location when required. The majority of the pieces forming thereof could weight no more than 50 kg and its package allows good mobility.

Once the device has been completely assembled, its structure is autonomous and does not require to be anchored to the floor or ballast to hold it in place. The design of component 1 has an additional support system which broadens its area avoiding oscillations. The design of the invention is compact and forms a solid and balanced geometry. As an example and not limitative its size could be around 1 meter to three meters high, 0.50 and 2 meters wide and between 0.20 and 0.90 meters deep.

The display system of the present invention can use an intelligent 32″ LCD screen, as main means for transmitting publicity messages, enriched with movements, sound and high resolution images. The technology of this screen allows feeding the information from compact or digital memories discarding the use of other reproduction devices which use more space and require complex connections. The information, being digital, can be changed or renewed in short time at no expenses in special printings and with the possibility of adding animated and sound contents. Nevertheless, said screen can also be a plasma, LED, cathode ray tube screens, etc.

Furthermore, this device has the ability of locating a rechargeable battery which can feed energy to the screen when required by the user, up to 6 hours, thus making this system totally independent.

The software managing the information of the screen was conceived in particular for the invention, so that, it organized data without the need of deposits or support of technical personnel; even the user may personalize his/her presentation in a very practical and intuitive manner. Renewing or changing the information projected on the screen can be done in real time through wireless connected devices, and if the user requires it, can operate from a central office coordinating various screens.

Some accessories such as tables, shelves, catalog holders or speakers to complete the exhibition can be coupled to components 3, lower and top columns (FIG. 3).

### Manufacturing Process

In order to obtain each one of the components or pieces forming the display system of the present invention conventional manufacturing processes are used, as described below:

Piece 1. Cutting and floding the metal sheet, reinforcing unions through welding.

Piece 2. Injection.

Piece 3. Extrusion.

Piece 4. Set of extruded pieces.

Piece 5. Die and pressing the metal sheet

Piece 6. Injection or thermoforming.

Piece 7. Die and pressing the sheet. Piece 8. Injection.

Piece 9. Injection or thermoforming.

Piece 10. Injection.

Once manufactured each one of these components according to the previously mentioned processes, and using the required materials complying with the specifications, we proceed with assembling each one of these components, as is shown in FIGS. 1 to 15 of the present invention.

### Example

A preferred demountable and portable digital graphical display system, such as that of the present invention and as a non-limitative example:

### Size:

1. Height: from 400 mm to 5000 mm.
2. Maximum weight: from 50 kg to 60 kg

In particular, a demountable and portable digital graphical information display system, such as that of the present invention is characterized in that it has a total height of 2 m; a width of 1.0 m; a deep of 0.5 m; and a weight of 50 kg. Nevertheless, the system of the present invention can achieve other configurations according to the needs.

### ADVANTAGES OF THE INVENTION

Now, the advantages of the digital graphical display system of the present invention, can be summarized in the following considerations compared to the conventional display systems.
The digital graphical display system of the present invention is demountable and portable as it can be transported to any place at any moment.
The display system allows that the disclosure of the digital graphical information bears more reach towards the receptor public. In that manner, the publicity is available to more users as the digital graphical information is available in any place and at any time.
The digital graphical display system of the present invention does not require complex and fix structures for its installation which may be costly.
Given that the system is so easy to assemble, no trained or specialized personnel are needed. The user can do it himself without needing accessories or tools.
The digital graphical display system of the present invention is versatile and simple compared to conventional devices of this kind, given its facility to assembling and disassembling.
The system of the present invention shows a novel design which makes it very attractive to the receptor.

Now, any skilled in the art, in particular a trained person having access to the teachings of the present invention, will recognize with no difficulty that modifications or variations of the demountable and portable digital graphical display system are possible, which modification or variations are considered to be within the scope and spirit of the invention. For example, it can be seen that any variety of components or materials can be used, and that the dimensions and geometric configurations can vary, always and when they comply with the practical purposes of the invention of providing a demountable and portable system. Thus, all the embodiments exposed in the present invention are not to be understood as limitative of the scope of the invention, which scope is only determined by the content of the following claims.

1. A demountable and portable digital graphical display system, characterized in that it comprises base (1) consisting of an elongated sheet exhibiting an inner surface (1a) and an outer surface (1b), and four support rods (1b′) transversally located under the sheet on its outer surface (1b); while along the sheet, longitudinal direction and on its inner surface (1a) there is provided an elongated piece (1c) along the entire sheet, and on which there are at least two support elements (1d, 1d′) in its ends; an elongated surface or housing (2) acting as a cover which exhibits an open wider end assembled to the base (1) in a perpendicular manner and a narrower closed end in which two reinforced apertures (2a, 2b) are located in its ends through which two lower elongated support elements or columns (3) pass, which are in turn inserted through one of its ends (3a) into each one of the support elements (1d, 1d′), the other ends (3a′) of said elongated support elements are coupled to two connecting pieces (4) through its ends (4a) while through the ends (4a′) of said connecting pieces (4) two other upper elongated support elements (3a′) are connected; said connecting pieces (4) have on its mid part a segment having grooves, and in such way are transversally holding between said upper elongated elements or columns (3) a union and support structure (5); this structure is covered by an elongated structure or housing (6), which has in one of its faces a stepping transverse recess (6a) for support on the union and support structure (5), and when the piece is inverted uses this recess to lean on a screen, and on the short sides of this elongated surface (6b) there is an inwards semi-aperture configuration for coupling in a complementary manner to the columns (3); at least an elongated rectangular support piece (7) is transversally coupled to the top columns (3) for adjusting a screen, through its concave-shaped ends, and having distant holes which allow them to be secured to the columns (3); the front part of the system includes two elongated pieces (8) having rounded edges on its front surface thus protecting the screen and an inner surface having fasteners along them for coupling to the system, while the rear part of the system on its upper portion includes a concave rectangular structure (9) having apertures distributed on each corner; and which are in turn covered by an elongated structure (6) corresponding to a completely closed piece, which in one of its faces has a stepping transverse recess (6a) to lean on the union and support structure (5), and when the piece is inverted such recess serve as support to the screen, and which short sides of said elongated surface (6b) exhibit an inwardly semi-aperture configuration for coupling in a complementary manner to the columns (3); a circular lid (10) is coupled to the ends of the upper columns (3a), said lid has a central hole and a groove which extends up to the final edge of the circle, and which further has a vertical piece for inserting into the channels of the upper columns (3) and a threaded hole for securing by a screw.

2. A digital graphical display system according to claim 1, characterized in that the base (1) includes along the sheet, in its longitudinal direction, and on its inner surface (1a), more than one elongated piece (1c) in order to have more support elements (1d, 1d′) available.

3. A digital graphical display system according to claim 1, characterized in that the base (1) can take an oval, elliptic, circular, square, rectangular, trapezoidal or polyhedral shape.

4. A digital graphical display system according to claim 1, characterized in that the base (1) has an oval shape.

5. A digital graphical display system according to claim 1, characterized in that the base (1) includes on its inner face floor grabbing systems as fix or demountable bases, wheels, sucks or height levelers.

6. A digital graphical display system according to claim 1, characterized in that the base (1) includes four support elements (1d, 1d′) provided on the pieces (1c).

7. A digital graphical display system according to claim 6, characterized in that the elongated surface or housing (2) which covers base (1) includes two apertures (2a, 2b).

8. A digital graphical display system according to claim 1, characterized in that the housing (2) can take an oval, elliptic, circular, square, rectangular, trapezoidal or polyhedral shape.

9. A digital graphical display system according to claim 8, characterized in that the housing (2) has an oval shape.

10. A digital graphical display system according to claim 1, characterized in that the elongated structure (6) corresponds to a structural covering housing, which on one of its faces has a stepping transverse recess for supporting on the union and support structure (5), and when the piece is inverted with this recess serves as support on a screen.

11. A digital graphical display system according to claim 1, characterized in that the upper and lower columns (3) have grooves on their outer surface.

12. A digital graphical display system according to claim 1, characterized in that the upper and lower columns (3) have circular, square, triangular, rectangular, polyhedral geometric configurations.

13. A digital graphical display system according to claim 12, characterized in that the upper and lower columns (3) have circular shape.

14. A digital graphical display system according to claim 1, characterized in that the upper and lower columns (3) can be coupled to accessories such as tables, shelves, catalog holders or speakers to complete the exhibition.
